(19) United States
(12) Patent Application Publication
(10) Pub. No.: US 2025/0113573 A1
(43) Pub. Date: Apr. 3, 2025

(54) TRANSITION METAL DICHALCOGENIDE MONOLAYER TRANSFER USING LOW STRAIN TRANSFER PROTECTIVE LAYER

(71) Applicant: Intel Corporation, Santa Clara, CA (US)

(72) Inventors: Andrey Vyatskikh, Hillsboro, OR (US); Paul B. Fischer, Portland, OR (US); Uygar E. Avci, Portland, OR (US); Chelsey Dorow, Portland, OR (US); Mahmut Sami Kavrik, Eugene, OR (US); Karthik Krishnaswamy, Portland, OR (US); Chia-Ching Lin, Portland, OR (US); Jennifer Lux, Hillsboro, OR (US); Kirby Maxey, Hillsboro, OR (US); Carl Hugo Naylor, Portland, OR (US); Kevin P. O'Brien, Portland, OR (US); Justin R. Weber, Beaverton, OR (US)

(73) Assignee: Intel Corporation, Santa Clara, CA (US)

(21) Appl. No.: 18/478,691

(22) Filed: Sep. 29, 2023

(51) Int. Cl. H01L 29/18; H01L 21/02; H01L 27/092; H01L 29/06; H01L 29/423; H01L 29/66; H01L 29/778; H01L 29/78

(52) U.S. Cl. CPC H10D 62/84; H01L 21/02485; H01L 21/02499; H01L 21/02568; H10D 30/024; H10D 30/47; H10D 30/6211; H10D 30/6735; H10D 62/118; H10D 84/853

(57) ABSTRACT

A low strain transfer protective layer is formed on a transition metal dichalcogenide (TMD) monolayer to enable the transfer of the TMD monolayer from a growth substrate to a target substrate with little or no strain-induced damage to the TMD monolayer. Transfer of a TMD monolayer from a growth substrate to a target substrate comprises two transfers, a first transfer from the growth substrate to a carrier wafer and a second transfer from the carrier wafer to the target substrate. Transfer of the TMD monolayer from the growth substrate to the carrier wafer comprises mechanically lifting off the TMD monolayer from the growth substrate. The low strain transfer protective layer can limit the amount of strain transferred from the carrier wafer to the TMD monolayer during lift-off. The carrier wafer and protective layer are separated from the TMD monolayer after attachment of the TMD monolayer to the target substrate.

### BACKGROUND

Transition metal dichalcogenides (TMD) monolayers are a candidate material for use in field effect transistors. One approach to integrating TMD monolayers into semiconductor device processing flows is to grow TMD monolayers on growth substrates and transfer the TMD monolayers to a target substrate on which field effect transistors utilizing TMD monolayers are to be fabricated.

### BRIEF DESCRIPTION OF THE DRAWINGS

FIGS. 1A-1F are cross-sectional views of a simplified example processing flow of transferring a first transition metal dichalcogenide (TMD) monolayer from a growth substrate to a target substrate.

FIGS. 2A-2F are cross-sectional views of a simplified example processing flow of transferring a second transition metal dichalcogenide (TMD) monolayer from a growth substrate to the target substrate of FIGS. 1D-1F.

FIG. 3 illustrates an example structure comprising a TMD monolayer stack former by layer transfer of the TMD monolayers from growth substrates to a target substrate.

FIG. 4 is a cross-sectional view of an example integrated circuit die comprising TMD monolayer stacks.

FIG. 5 illustrates an example method of transferring a TMD monolayer from a growth substrate to a target substrate.

FIG. 6 is a top view of a wafer and dies that may be included in any of the microelectronic assemblies disclosed herein.

FIG. 7 is a cross-sectional side view of an integrated circuit device that may be included in any of the microelectronic assemblies disclosed herein.

FIGS. 8A-8D are simplified perspective views of example planar, FinFET, gate-all-around, and stacked gate-all-around transistors.

FIGS. 9A and 9B are simplified perspective and cross-sectional views of example forksheet gate-all-around transistors.

FIGS. 10A-10B are simplified perspective and cross-sectional views, respectively, of an example complementary field-effect-transistor (CFET) architecture.

FIG. 11 is a cross-sectional side view of an integrated circuit device assembly that may include any of the microelectronic assemblies disclosed herein.

FIG. 12 is a block diagram of an example electrical device that may include integrated circuit dies comprising TMD monolayers transferred from a growth layer and/or one or more of the microelectronic assemblies disclosed herein.

### DETAILED DESCRIPTION

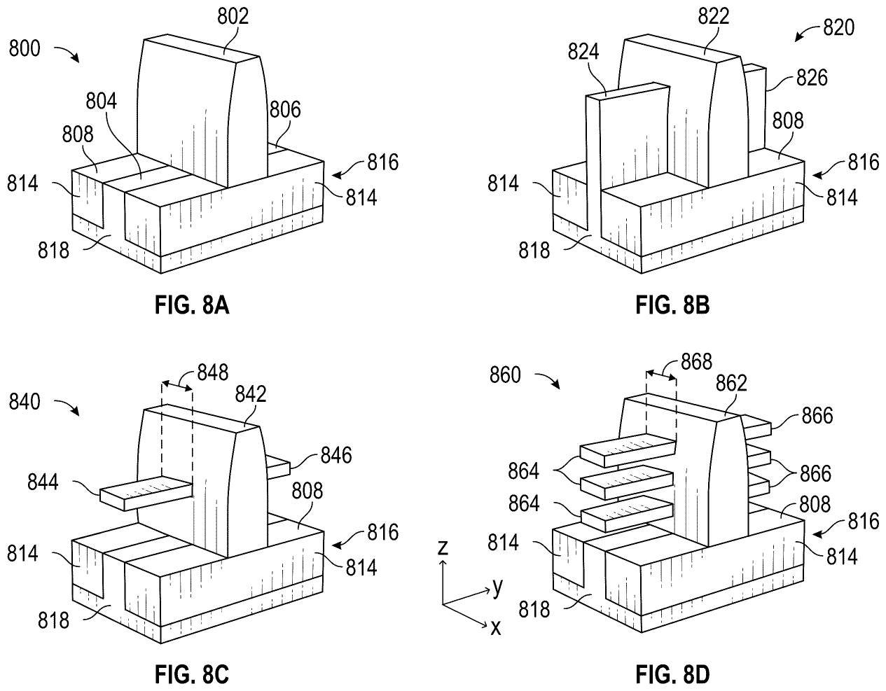

Transition metal dichalcogenides (TMD) monolayers are a candidate material for use in field effect transistors (FETs). For example, TMD monolayers are a candidate material for use as the channel region material in nanoribbon (nanosheet, nanowire) transistors of the type illustrated in FIG. 8D. One approach to integrating TMD monolayers into semiconductor device processing flows is to grow TMD monolayers on growth substrates and transfer the TMD monolayers to a target substrate on which FETs comprising TMD monolayers are to be formed. One advantage of growing TMD monolayers on a substrate that is different from a target substrate is that the target substrate is spared from the high-temperature processing conditions under which TMD monolayers can be grown. High-temperature TMD growth conditions can damage the substrate upon which the TMDs are grown and, if the TMDs are grown on the same substrate upon which integrated circuit dies are fabricated, the TMD growth process can consume a large portion of the limited thermal budget of a semiconductor device processing flow.

One challenge in transferring TMD monolayers from a growth substrate to a target substrate is avoiding damage to the TMD monolayer during mechanical lift-off of the TMD monolayer from the growth substrate. This damage in the TMD monolayer can take the form of voids, cracks, wrinkles, etc. This damage can result from strain in a layer attached to the TMD monolayer being transferred to the TMD monolayer during the lift-off process. In some existing approaches to address this strain transfer issue, an organic material, such as PMMA (polymethyl methacrylate), has been used as a protective layer formed on the TMD monolayer. However, PMMA can be difficult to remove during subsequent processing and can leave carbon residue behind on the TMD monolayer. This carbon residue be detrimental to the performance of any transistors comprising such TMD monolayers. In other approaches, nickel has been used as a protective layer, but nickel can still allow enough strain to be transferred during mechanical lift-off to cause damage to a TMD monolayer.

Disclosed herein are TMD monolayer transfer technologies that utilize a low-strain transfer material as a protective layer during layer transfer. The protective layer can be a metal or metal compound formed on the TMD monolayer while the TMD monolayer is still attached to the growth substrate. After attachment of a carrier wafer to the protective layer, the carrier wafer stack (comprising the carrier wafer, protective layer, and TMD monolayer) is mechanically lifted-off of the growth substrate and the protective layer limits the amount of strain in the carrier wafer that is transferred to the TMD monolayer. The protective layers disclosed herein can be effective in limiting the amount of strain transferred due to lattice mismatch between the protective layer and the carrier wafer and the protective layer's low reactivity with sulfur (which can comprise the chalcogen of some TMDs). Thus, the disclosed layer transfer technologies have the advantage of enabling TMD monolayer transfer with less (or even zero) damage to the TMD monolayer relative to some existing layer transfer processes (such as those using nickel or PMMA as a protective layer). Another advantage is the absence of organic residue left on the TMD monolayer after layer transfer and protective layer removal. Some protective layer residue may remain on a TMD monolayer surface after layer transfer, but as the protective layer is inorganic, the protective layer residue may not be as difficult to remove in subsequent processing as organic material residue. The layer transfer technologies disclosed herein can be used to build stacks comprising multiple TMD monolayers. These stacks can be used in the gate stack of nanoribbon FETs, with the TMD monolayers acting as channel regions for the nanoribbon FETS.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or in any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous.

Terms modified by the word “substantially” include arrangements, orientations, spacings, or positions that vary slightly from the meaning of the unmodified term. For example, the portion of a first layer or feature that is substantially perpendicular to a second layer or feature can include a first layer or feature that is +/−20 degrees from a second layer or feature, a first surface that is substantially parallel to a second surface can include a first surface that is within several degrees of parallel from the second surface, and a layer that is substantially planar can include layers that comprise some dishing, bumps, or other non-planar features resulting from processing variations and/or limitations. Further, a first layer that is substantially coplanar with another second layer includes first layers that are offset by a small amount due to processing variations and limitations. Moreover, a stated value for a dimension, feature, or characteristic qualified by the term “about” includes values within +/−10% of the stated value. Similarly, a stated range of values for a dimension, feature, or characteristic includes values within 10% of the listed upper and lower values for the range.

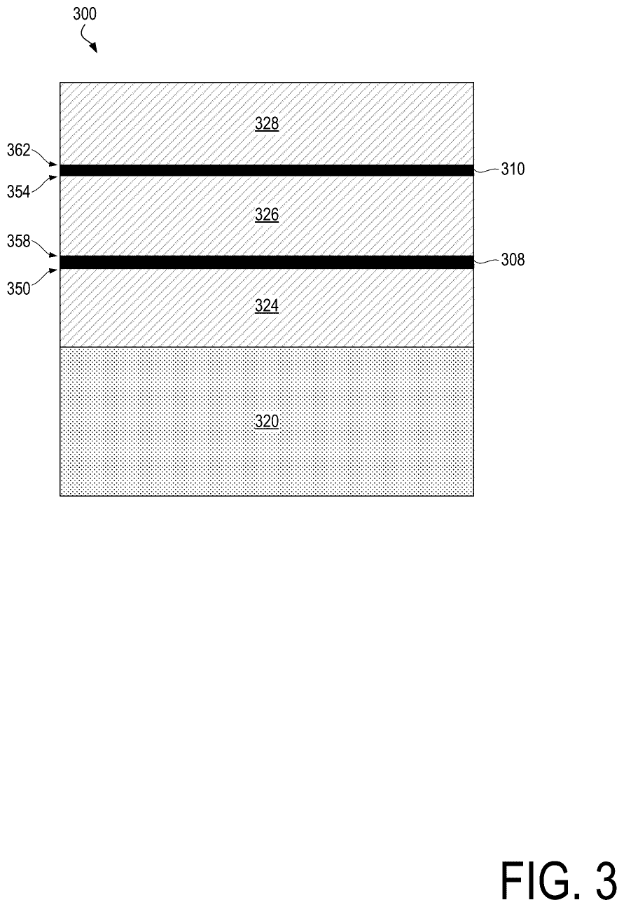

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components. For example, with reference to FIG. 3, the TMD monolayer 308 is located on the target substrate 320 with an intervening layer 324.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

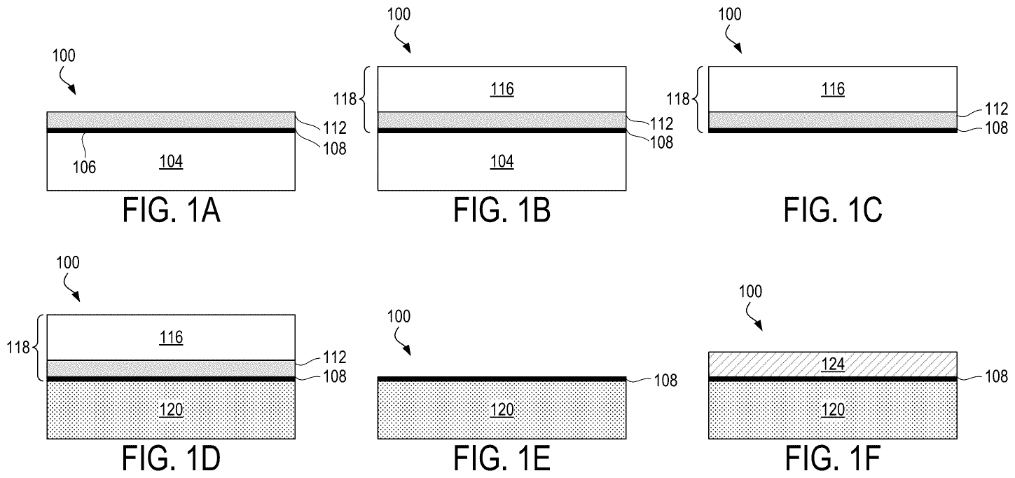

As used herein, the phrase “positioned between” in the context of a first layer or component positioned between a second layer or component and a third layer or component refers to the first layer or component being directly physically attached to the second and/or third parts or components (no layers or components between the first and second layers or components or the first and third layers or components) or physically attached to the second and/or third layers or components via one or more intervening layers or components. For example, with reference to FIG. 3, the layer 326 is positioned between TMD monolayers 308 and 310, and with reference to FIG. 1B, the TMD monolayer 108 is positioned between the target substrate 120 and the carrier wafer 116 with a protective layer 112 between the TMD monolayer 108 and the carrier wafer 116.

Certain terminology may also be used herein for the purpose of reference only, and thus are not intended to be limiting. For example, terms such as “upper,” “lower,” “above,” “below,” “bottom,” and “top” refer to directions in the Figures to which reference is made. Terms such as “front,” “back,” “rear,” and “side” describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “integrated circuit component” refers to a packaged or unpackaged integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims.

FIGS. 1A-1F are cross-sectional views of a simplified example processing flow of transferring a first transition metal dichalcogenide (TMD) monolayer from a growth substrate to a target substrate. Any of the fabrication methods or processes described herein, including method 500, may be performed using any suitable microelectronic fabrication techniques. For example, film deposition-such as depositing layers, filling (backfilling) portions of layers (e.g., filling removed portions of layers or removed layers), and filling via or contact openings—may be performed using any suitable deposition techniques, including, for example, chemical vapor deposition (CVD), metalorganic chemical vapor deposition (MOCVD), molecular beam epitaxy (MBE), atomic layer deposition (ALD), sputtering and/or physical vapor deposition (PVD). Moreover, layer patterning-such as dielectric or metal layer patterning—may be performed using any suitable techniques, such as photolithography-based patterning and etching (e.g., dry etching or wet etching).

FIG. 1A is a cross-sectional view of an example structure comprising a TMD monolayer 108 formed on a surface 106 of a growth substrate 104, with a protective layer 112 formed on the TMD monolayer 108. In some embodiments, the TMD monolayer 108 can be epitaxially grown on the surface 106 of the growth substrate 104. In some embodiments, the protective layer 112 can be deposited on the TMD monolayer 108. The TMD monolayer 108 is positioned between the protective layer 112 and the growth substrate 104.

TMDs have the chemical formula MX₂ where M is a transition metal and X is a chalcogen. A TMD monolayer comprises a middle layer of M atoms sandwiched between two layers of X atoms. TMD monolayers, which can also be referred to as 2D TMD layers, are less than 1 nanometer thick. The TMD monolayers disclosed in any of the embodiments described or referenced herein can comprise titanium, molybdenum, tungsten, platinum, erbium, lanthanum, rhodium, niobium, or another transition metal; with sulfur, selenium or tellurium as the chalcogen. That is, in some embodiments, the TMD monolayers described or referenced herein can be molybdenum disulfide (MoS₂), molybdenum diselenide (MoSe₂), molybdenum ditelluride (MoTe₂), titanium disulfide (TiS₂), titanium diselenide (TiSe₂), titanium ditelluride (TiTe₂), tungsten disulfide (WS2), tungsten diselenide (WSe₂), tungsten ditelluride (WTe₂), platinum disulfide (PtS₂), platinum diselenide (PtSe₂), platinum ditelluride (PtTe₂), erbium disulfide (ErS₂), erbium diselenide (ErSe₂), erbium ditelluride (ErTe₂), rhodium disulfide (RhS₂), rhodium diselenide (RhSe₂), rhodium ditelluride (RhTe₂), lanthanum disulfide (LaS₂), lanthanum diselenide (LaSe₂), lanthanum ditelluride (LaTe₂), niobium disulfide (NbS₂), niobium diselenide (NbSe₂), niobium ditelluride, or another disulfide, disulfide, or ditelluride TMD.

In some embodiments, the TMD monolayer comprises a TMD alloy of the form ABX₂ where A and B are transition metals and X is a chalcogen. Thus, in some embodiments, the TMD monolayer can be, for example, Mo₍₁₋ₓ₎WₓS₂, Mo₍₁₋ₓ₎WₓSe₂, or W₍₁₋ₓ₎NbₓS₂.

In any of the embodiments described or referenced herein, the protective layer can be antimony, zinc, tin, platinum, lead, cobalt, chromium, ruthenium, palladium, or manganese. In other embodiments, the protective layer can comprise a molybdenum oxide (a compound comprising molybdenum and oxygen, such as MoO₂ or MoO₃), titanium nitride (TiN), silicon dioxide (SiO₂), hafnium oxide (HfO₂, a material comprising hafnium and oxygen), titanium dioxide (TiO₂, a material comprising titanium and oxygen), aluminum oxide (Al₂O₃, a material comprising aluminum and oxygen), or silicon nitride (a material comprising silicon and nitrogen, such as Si₃N₄, SiₓN_{y}). In any of the embodiments described or referenced herein, the growth substrate can comprise sapphire, silicon, silicon with a layer (e.g., silicon dioxide (SiO₂), silicon carbide, graphene) on top of a bulk silicon region or other suitable material.

FIG. 1B is a cross-sectional view of the example structure 100 after attachment of a carrier wafer 116 to the protective layer 112. A carrier wafer stack 118 comprises the carrier wafer 116, the protective layer 112, and the TMD monolayer 108. The carrier wafer stack 118 further comprises a bonding layer (not shown) to enable attachment of the carrier wafer 116 to the protective layer 112. In some embodiments, one or more additional layers can be positioned between the protective layer 112 and the carrier wafer 116 to control mechanical properties of the carrier wafer stack 118. In any of the embodiments described or referenced herein, the carrier wafer 116 can be a wafer, panel, or other structure that provides mechanical support to layers, features, or components attached to the carrier wafer 116. In any of the embodiments described or referenced herein, the carrier wafer 116 can comprise silicon, glass (e.g., amorphous solid glass, such as aluminosilicate, borosilicate, alumino-borosilicate, silica, and fused silica), sapphire, plastic, silicon carbide (SiC), gallium arsenide (GaAs), or other suitable material. In any of the embodiments described or referenced herein, the bonding layer between the protective layer 112 and the carrier wafer 116 can comprise silicon and oxygen (e.g., SiOₓ, SiO₂), silicon and nitrogen (e.g., Si₃N₄, SiₓN_{y}), silicon, carbon, and nitrogen (e.g., SiCN), or another suitable material.

FIG. 1C is a cross-sectional view of the example structure 100 after mechanical exfoliation of the carrier wafer stack 118 from the growth substrate 104. Mechanical exfoliation (or separation) of the carrier wafer stack 118 from the growth substrate 104 can comprise mechanical lift-off of the carrier wafer stack 118 from the growth substrate 104. The presence of the protective layer 112 between the carrier wafer 116 and the TMD monolayer 108 can limit the transfer of strain from the carrier wafer 116 to the TMD monolayer 108, which can prevent or limit damage to the TMD monolayer 108, which can take the form of, for example, voids, cracks, and/or wrinkles in the TMD monolayer 108.

FIG. 1D is a cross-sectional view of the example structure 100 after attachment of the carrier wafer stack 118 to a target substrate 120. The carrier wafer stack 118 can be attached to the carrier wafer stack 118 via bonding, such as by fusion, vacuum, or thermo-compression bonding. The target substrate 120 can be a substrate on which transistors and/or other features into which the TMD monolayer 108 is to be integrated. In any of the embodiments described or referenced herein, the target substrate can comprise a crystalline substrate formed using a bulk silicon or a silicon-on-insulator (SOI) substructure. In some embodiments, the target substrate 120 may be formed using alternative materials, which may or may not be combined with silicon, that include, but are not limited to, germanium. Further materials classified as group II-VI, III-V, or IV may also be used to form the target substrate 120. Although a few examples of materials from which the target substrate 120 may be formed are described here, any material that may serve as a foundation for an integrated circuit device may be used.

FIG. 1E is a cross-sectional view of the example structure 100 after release of the carrier wafer 116 from the carrier wafer stack 118 and removal of the protective layer 112 from the TMD monolayer 108. The carrier wafer bonding layer and any additional layers that were positioned between the carrier wafer 116 and the protective layer 112 are removed along with the protective layer 112.

FIG. 1F is a cross-sectional view of the example structure 100 after formation of a layer 124 on the TMD monolayer 108. In some embodiments, the layer 124 is a sacrificial layer that is replaced by one or more functional layers during subsequent processing, such as by a gate dielectric layer or one or more gate metal electrode layers, as will be discussed in more detail below. In some embodiments, the layer 124 is not a sacrificial layer and comprises one or more functional layers that form, for example, part of an active device, such as a field effect transistor. In some embodiments, the layer 124 can comprise oxygen.

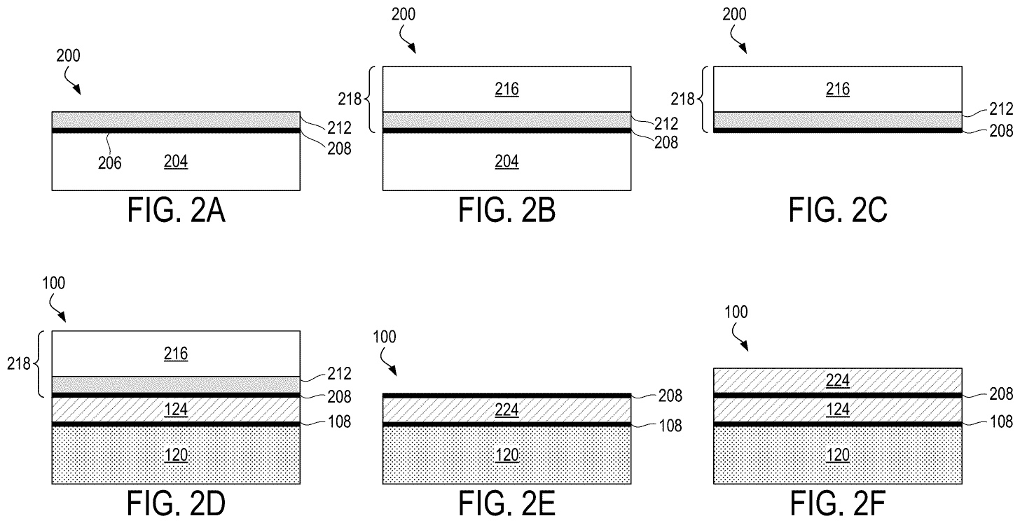

FIGS. 2A-2F are cross-sectional views of a simplified example processing flow of transferring a second transition metal dichalcogenide (TMD) monolayer from a growth substrate to the target substrate 120 of FIGS. 1D-1F. FIGS. 2A-2F illustrate the same processing flow as illustrated in FIGS. 1A-1F, with FIGS. 2A-2C illustrating the same processing flow as illustrated in FIGS. 1A-1C to create a second TMD monolayer on a growth substrate. Features or structures in FIGS. 2A-2F having similar numbers as in FIGS. 1A-1C (e.g., 208 and 108, 212 and 112) can comprise any of the materials described above as being used in the corresponding feature or structure in FIGS. 1A-1F.

FIG. 2A is a cross-sectional view of a structure 200 comprising a second TMD monolayer 208 formed on a surface 206 of a growth substrate 204, with a protective layer 212 formed on the TMD monolayer 208. FIG. 2B is a cross-sectional view of the structure 200 after attachment of a carrier wafer 216 to the protective layer 212. A carrier wafer stack 218 comprises the carrier wafer 216, the protective layer 212, and the TMD monolayer 208. FIG. 2C is a cross-sectional view of the structure 200 after mechanical exfoliation of the carrier wafer stack 218 from the growth substrate 204.

FIGS. 2D-2F illustrate the transfer of the second TMD monolayer 208 to the structure 100 of FIG. 1F to create a two-layer stack of TMD monolayers. FIG. 2D illustrates the structure 100 of FIG. 1F after attachment of the carrier wafer stack 218 to the layer 124 on the target substrate 120. FIG. 2E is a cross-sectional view of the structure 100 after release of the carrier wafer 216 from the carrier wafer stack 218 and removal of the protective layer 212 from the TMD monolayer 208. FIG. 2F illustrates the structure 100 after growth of a layer 224 on the second TMD monolayer 208. In some embodiments, additional TMD monolayers can be grown on a growth substrate and transferred to the target substrate 120 to fabricate a TMD monolayer stack comprising more than the two TMD monolayers (108, 208) illustrated in FIG. 2F. In some embodiments, a TMD monolayer stack can comprise five or more TMD monolayers.

FIG. 3 illustrates an example structure comprising a TMD monolayer stack formed by layer transfer of TMD monolayers from growth substrates to a target substrate. The structure 300 comprises TMD monolayers 308 and 310 positioned above a target substrate 320. A layer 324 is positioned between and adjacent to the target substrate 320 and the monolayer 308, a layer 326 is positioned between and adjacent to the monolayers 308 and 310, and a layer 328 is positioned above and adjacent to the monolayer 310. The structure 300 thus differs from the structure 100 illustrated FIG. 2F comprising a TMD monolayer stack with two TMD monolayers in that the structure 300 comprises a layer (324) between the bottommost TMD monolayer (308) in the stack and the target substrate 320. In any of the embodiments described or referenced herein, a layer can be positioned between the bottommost TMD monolayer of a TMD monolayer stack and a target substrate. This layer can comprise oxygen and can be either a sacrificial layer or a functional layer, as described above with respect to layer 124.

In some embodiments, after transfer of a TMD monolayer from a growth substrate to a target substrate and separation of the protective layer and the carrier wafer from the transferred TMD monolayer, a residue of protective layer material may remain on the surface of the TMD monolayer to which the protective layer was attached. This protective layer residue can remain after formation of a sacrificial layer on the TMD monolayer (e.g., layer 124, 224, 324) and can thus reside at an interface between the TMD monolayer and a layer formed on the surface TMD monolayer where the protective layer was formed. With reference to FIG. 3, this protective layer residue can be located at an interface 358 between the monolayer 308 and the layer 326 and at an interface 362 between the monolayer 310 and the layer 328. In some embodiments, the protective layer residue can take the form of individual atoms or molecules of the protective layer metal or clusters of such atoms or molecules. Thus, the protective layer residue can comprise, for example, individual or clusters of antimony, zinc, tin, platinum, lead, cobalt, chromium, ruthenium, palladium, or manganese atoms; or individual or clusters of molybdenum oxide, titanium nitride, silicon dioxide, hafnium oxide, titanium dioxide, aluminum oxide, or silicon nitride molecules. In some embodiments, the concentration of protective layer material residue peaks directly adjacent to the interface between the TMD monolayer and the layer positioned above the TMD monolayer. In some embodiments, the presence of any atoms of the protective layer material at this interface can indicate that the TMD monolayer was grown on a separate substrate from the target substrate and transferred to the target substrate.

Transfer of a TMD monolayer from a growth substrate to a target substrate can also be evidenced by the absence of chalcogen (e.g., sulfur, selenium, tellurium) residue at the interface between a TMD monolayer and the layer (or substrate) below the TMD monolayer after transfer of the TMD monolayer to the target substrate. For example, with reference to FIG. 3, the chalcogen of TMD monolayers 308 and 310 may not be present in the layer 324 (either near an interface 350 between the TMD monolayer 308 and the layer 324 or anywhere in the layer 324) or in layer 326 (near an interface 354 between the TMD monolayer 310 and layer 326 or anywhere in the layer 326). With reference to FIGS. 1F and 2F, the chalcogen of TMD monolayer 108 may not be present in the target substrate 120. In some embodiments, the absence of the TMD chalcogen residue can be indicated by an atomic composition of 0.1% or less of the TMD chalcogen at an interface or in a layer. In contrast, at interfaces between a TMD monolayer and an underlying layer upon which the TMD was grown, chalcogen residue may be found at this interface. This chalcogen residue can take the form of individual or clusters of chalcogen atoms at the interface between the TMD monolayer and the underlying layer or in the underlying layer near the interface with the TMD monolayer.

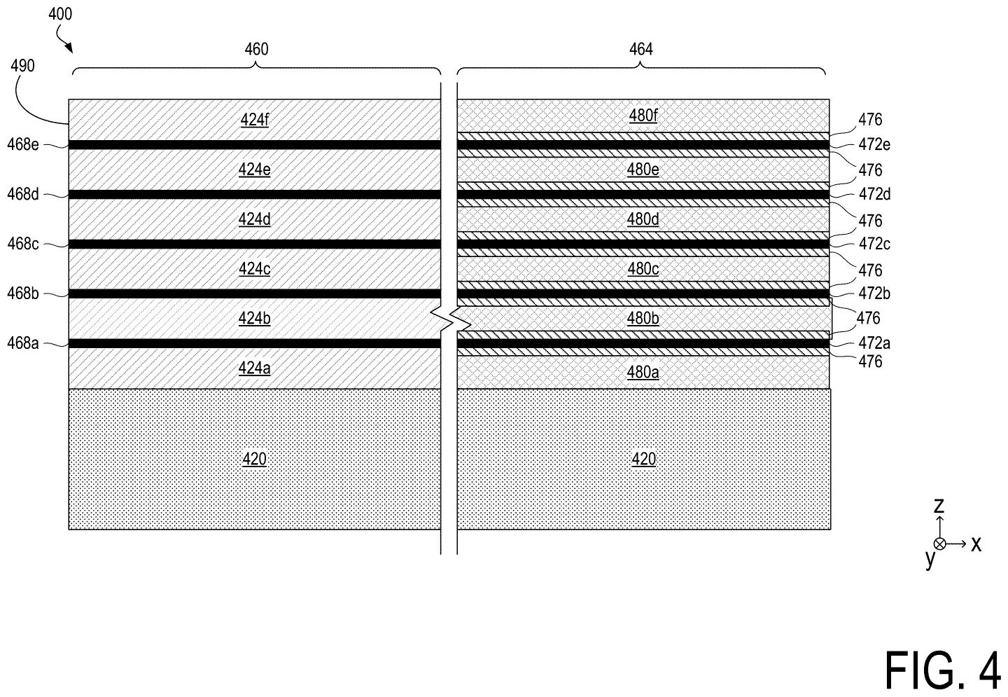

FIG. 4 is a cross-sectional view of an example integrated circuit die comprising stacks of TMD monolayers. The integrated circuit die 400 comprises first and second TMD monolayer stacks 460 and 464, respectively, positioned above a target substrate 420. Stacks 460 and 464 comprise five TMD monolayers 468 (468a-468e) and 472 (472a-472e), respectively. TMD monolayer stack 460 is located in a buffer region of the integrated circuit die 400 and TMD monolayer stack 464 is part of a nanoribbon field effect transistor (FET). The nanoribbon FET comprises the TMD monolayers 472. The buffer region of the integrated circuit die 400 is a region at the periphery of the integrated circuit die 400 that does not comprise nanoribbon transistors comprising TMD monolayers. The TMD monolayer stack 460 thus can be positioned laterally between a transistor utilizing TMD monolayers, such as the nanoribbon transistor employing the gate stack 464 and an integrated circuit die edge, such as die edge 490.

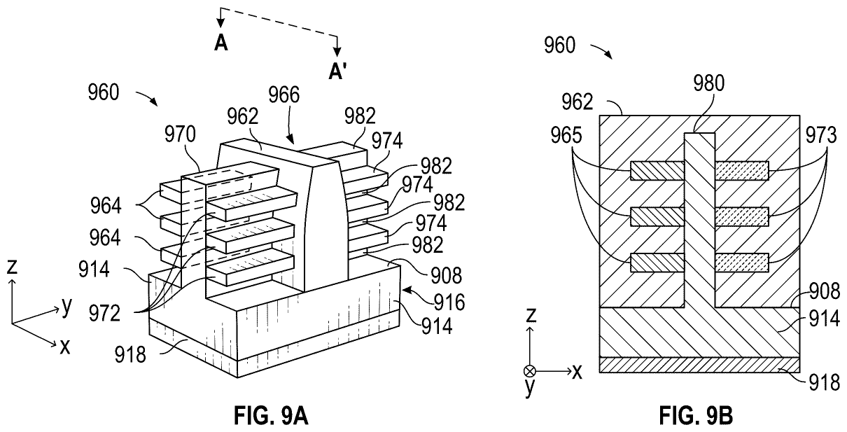

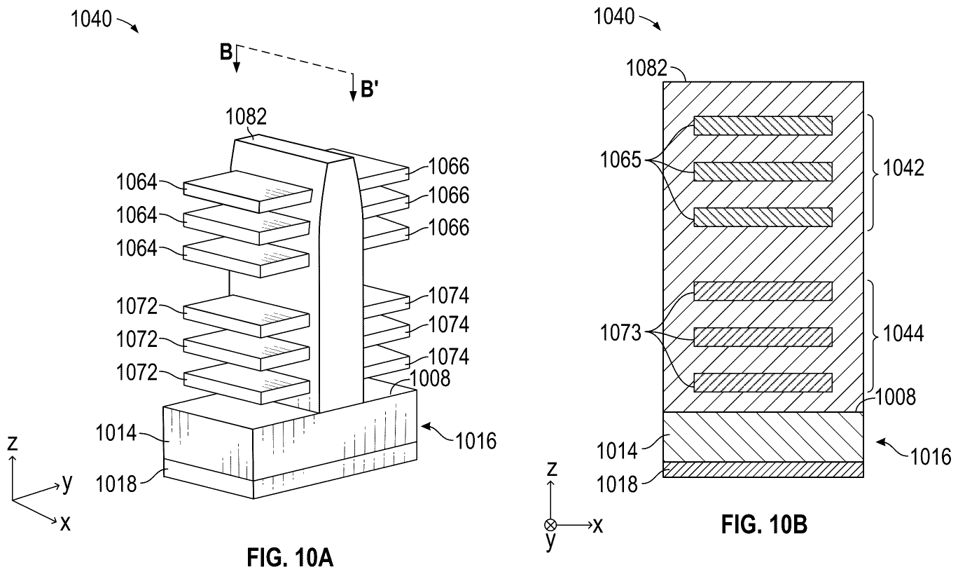

Although FIG. 4 illustrates a TMD monolayer stack 464 used in a nanoribbon FET, TMD monolayer stacks can be used in other types of transistor architectures, such as forksheet or complementary FET (CFET) transistors, as illustrated in FIGS. 9A-9B and FIGS. 10A-10B, respectively.

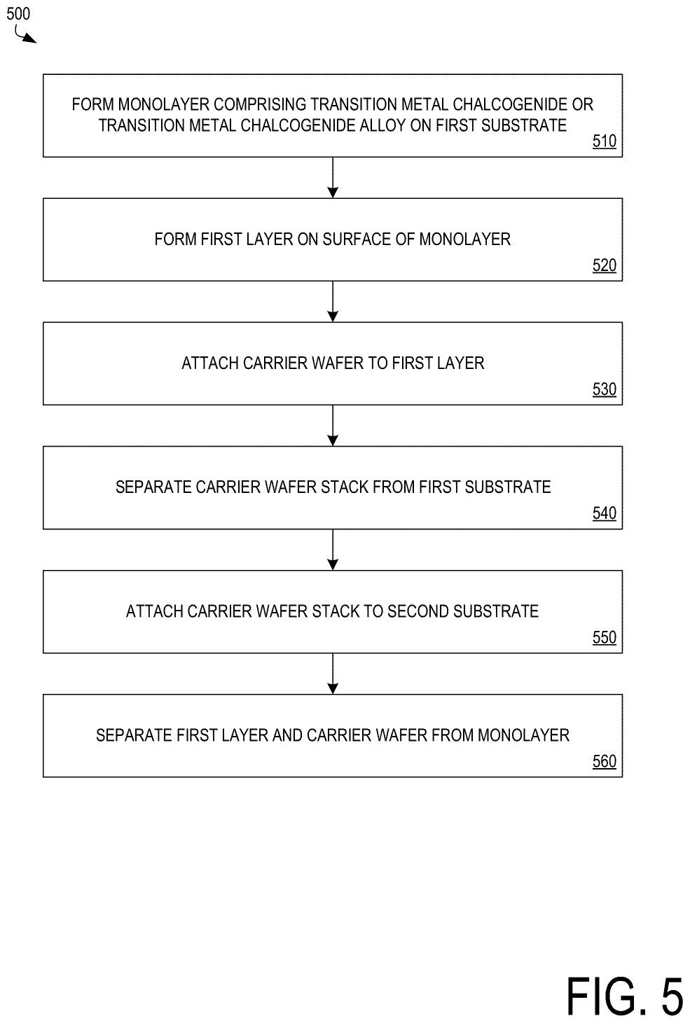

The pairs TMD monolayers 468 and 472 that are illustrated as being vertically aligned in FIG. 5 can be portions of a TMD monolayer transferred from a growth substrate to the target substrate 420. For example, monolayers 468a and 472a can be portions of a first TMD monolayer transferred to the target substrate 420, monolayers 468b and 472b can be portions of a second transferred TMD monolayer, etc. As such, TMD monolayers illustrated as being vertically aligned in FIG. 4 are substantially coplanar. For example, TMD monolayer 468a is substantially coplanar with TMD monolayer 472a and TMD monolayer 468b is substantially coplanar with TMD monolayer 472b.

The TMD monolayer stack 460 comprises layers 424. Layers 424b-424e are positioned between and adjacent to vertically adjacent TMD monolayers 468 (e.g., 468b and 468c, 468c and 468d), layer 424f is positioned above and adjacent to the topmost TMD monolayer 468e, and layer 424a is positioned below and adjacent to the bottommost gate dielectric layer 468a. The layers 424b-424f can be sacrificial layers that are formed on the TMD monolayers 468a-f after transfer of the TMD monolayer to the target substrate 420. In some embodiments, the layers 424 can comprise oxygen.

As mentioned above, a nanoribbon FET included in the integrated circuit die 400 can comprise the TMD monolayer stack 464, with the channel regions of the nanoribbon FET comprising the TMD monolayers 472. As part of forming the gate stack of the nanoribbon FET, the layers formed between and adjacent to the TMD monolayers 472 as part of the layer transfer process (e.g., layers 424) are replaced with layers that function as gate dielectric and gate electrode regions of the nanoribbon FET. Gate dielectric layers 476 are formed adjacent to top and bottom surfaces of the individual TMD monolayers 472 and gate electrode regions 480 are formed on the gate dielectric layers 476. For example, gate electrode regions 480b, 480c, 480d, and 480e are positioned between and adjacent to the gate dielectric layers 476 attached to vertically adjacent TMD monolayers 472 (e.g., 472b and 472c), gate electrode region 480f is positioned above and adjacent to the topmost gate dielectric layer 476e, and gate electrode region 480a is positioned below and adjacent to the bottommost gate dielectric layer 476a.

The gate dielectric layers 476 can comprise one or more layers comprising any of the materials that can be part of any gate dielectric layer described or referenced herein, such as the gate dielectric of gate 722. The gate electrode regions comprise 480 can comprise any material that can be part of any gate electrode for any transistor described herein, such as the gate electrode regions of gate 722 for a p-type (PMOS) transistor or an n-type (NMOS) transistor.

In some embodiments, as part of forming the nanoribbon FET stack, any protective layer residue residing on top surfaces of the TMD monolayer 472 after layer transfer is removed to ensure a high-quality gate dielectric-channel (gate dielectric region 476-TMD monolayer 472) interface. The existence of protective layer residue at these interfaces in the stack 464 can be detrimental to transistor performance. Protective layer material residue can still be present on the top surfaces of the TMD monolayers 468 in the TMD monolayer stack 460 in the buffer region of the integrated circuit die after the formation of transistors in the die 400. The interfaces between the bottom surfaces of the TMD monolayers in both stacks 460 and 464 and adjacent layers are devoid of chalcogen residue (or have an atomic composition of 0.1% or less of the chalcogen used in the TMD monolayer layers 468 and 472).

In embodiments where there is a layer between the bottommost TMD monolayer in a TMD monolayer stack and a target substrate, such as layer 324 in FIG. 3, the layer can have a thickness less than an equivalent protective layer on the target substrate if the bottommost TMD monolayer were grown on the target substrate to protect the target substrate from damage due to the high-temperature TMD monolayer growth conditions. In some embodiments, the thickness of the layer between a TMD monolayer nearest the surface of the target substrate that was transferred from a growth substrate to a target substrate is in a range of about 9 nanometers to about 15 nanometers.

In some embodiments, the integrated circuit die 400 can comprise TMD monolayer stacks 460 in regions of the integrated circuit die 400 other than in a peripheral buffer region. A TMD monolayer stack 460 can be located in any region of an integrated circuit die where there are not transistors or other devices employing transferred TMD monolayers.

FIG. 5 illustrates an example method of transferring a TMD monolayer from a growth substrate to a target substrate. The method 500 can be performed by an integrated circuit component manufacturer. At 510, a monolayer is formed on a first substrate, the monolayer comprising a transition metal dichalcogenide or transition metal dichalcogenide. At 520, a first layer is formed on a surface of the monolayer. At 530, a carrier wafer is attached to the first layer, wherein a carrier wafer stack comprises the monolayer, first layer, and the carrier wafer. At 540, the carrier wafer stack is separated from the first substrate. At 550, the carrier wafer stack is attached to a second substrate. At 560, the first layer and the carrier wafer are separated from the monolayer. In other embodiments, the method 500 can comprise additional actions. In one example, the method 500 can further comprise forming a second layer on the surface of the monolayer after separating the first layer and the carrier wafer from the monolayer.

The integrated circuit components and microelectronic structures or assemblies described herein can be used in any processor unit or integrated circuit component described or referenced herein. An integrated circuit component comprising embedded alignment markers can be attached to a printed circuit board (motherboard, mainboard). In some embodiments, one or more additional integrated circuit components or other components (e.g., battery, memory, antenna) can be attached to the printed circuit board. In some embodiments, the printed circuit board and the integrated circuit component can be located in a computing device that comprises a housing that encloses the printed circuit board and the integrated circuit component.

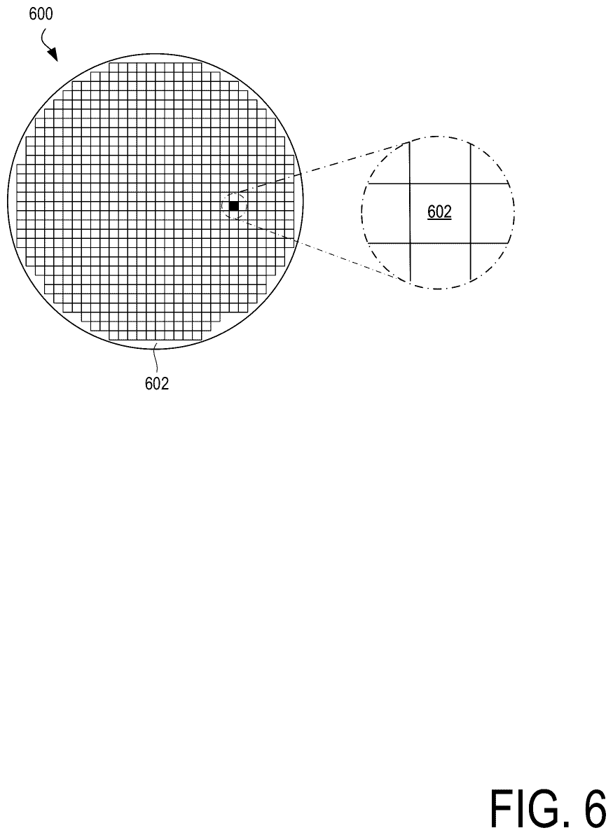

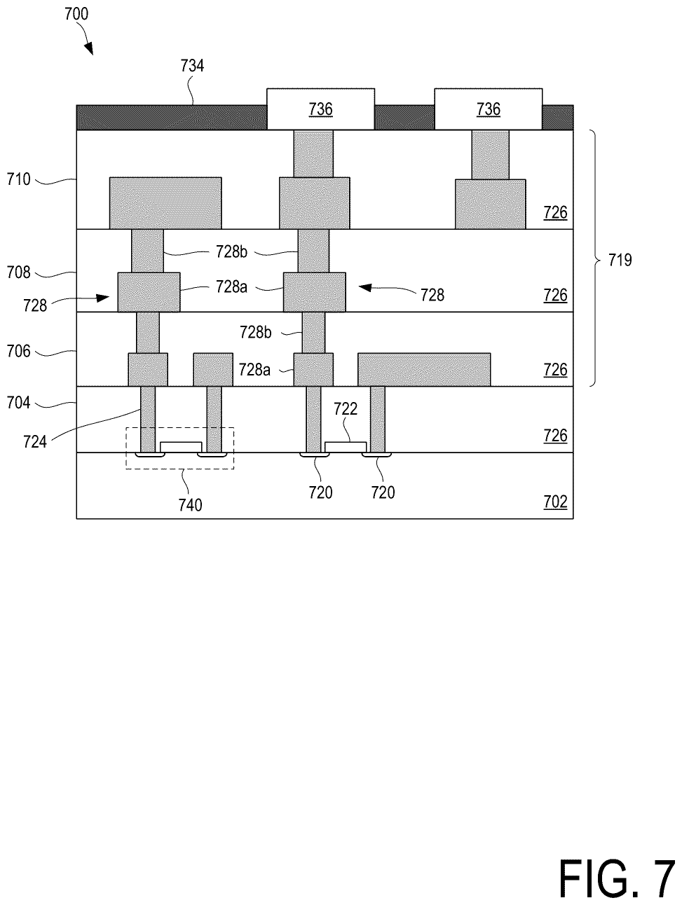

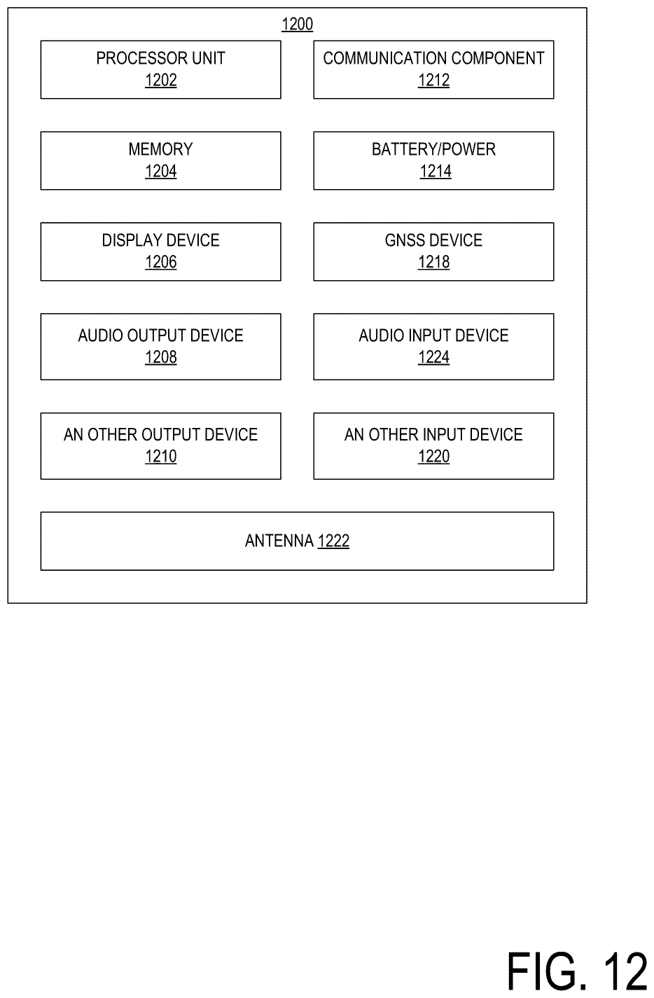

FIG. 6 is a top view of a wafer 600 and dies 602 that may be included in any of the microelectronic assemblies disclosed herein (e.g., die 400). The wafer 600 may be composed of semiconductor material and may include one or more dies 602 having integrated circuit structures formed on a surface of the wafer 600. The individual dies 602 may be a repeating unit of an integrated circuit product that includes any suitable integrated circuit. After the fabrication of the semiconductor product is complete, the wafer 600 may undergo a singulation process in which the dies 602 are separated from one another to provide discrete “chips” of the integrated circuit product. The die 602 may be any of the dies disclosed herein. The die 602 may include one or more transistors (e.g., some of the transistors 740 of FIG. 7, discussed below), supporting circuitry to route electrical signals to the transistors, passive components (e.g., signal traces, resistors, capacitors, or inductors), and/or any other integrated circuit components. In some embodiments, the wafer 600 or the die 602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 602. For example, a memory array formed by multiple memory devices may be formed on a same die 602 as a processor unit (e.g., the processor unit 1202 of FIG. 12) or other logic that is configured to store information in the memory devices or execute instructions stored in the memory array. Various ones of the microelectronic assemblies disclosed herein may be manufactured using a die-to-wafer assembly technique in which some dies are attached to a wafer 600 that include others of the dies, and the wafer 600 is subsequently singulated.

FIG. 7 is a cross-sectional side view of an integrated circuit device 700 that may be included in any of the microelectronic assemblies disclosed herein. One or more of the integrated circuit devices 700 may be included in one or more dies 602 (FIG. 6). The integrated circuit device 700 may be formed on a die substrate 702 (e.g., the wafer 600 of FIG. 6) and may be included in a die (e.g., the die 602 of FIG. 6). The die substrate 702 may be a semiconductor substrate composed of semiconductor material systems including, for example, n-type or p-type materials systems (or a combination of both). The die substrate 702 may include, for example, a crystalline substrate formed using a bulk silicon or a silicon-on-insulator (SOI) substructure. In some embodiments, the die substrate 702 may be formed using alternative materials, which may or may not be combined with silicon, that include, but are not limited to, germanium, carbon, indium antimonide, lead telluride, indium arsenide, indium phosphide, gallium arsenide, or gallium antimonide. Further materials classified as group II-VI, III-V, or IV may also be used to form the die substrate 702. Although a few examples of materials from which the die substrate 702 may be formed are described here, any material that may serve as a foundation for an integrated circuit device 700 may be used. The die substrate 702 may be part of a singulated die (e.g., the dies 602 of FIG. 6) or a wafer (e.g., the wafer 600 of FIG. 6).

The integrated circuit device 700 may include one or more device layers 704 disposed on the die substrate 702. The device layer 704 may include features of one or more transistors 740 (e.g., metal oxide semiconductor field-effect transistors (MOSFETs)) formed on the die substrate 702. The transistors 740 may include, for example, one or more source and/or drain (S/D) regions 720, a gate 722 to control current flow between the S/D regions 720, and one or more S/D contacts 724 to route electrical signals to/from the S/D regions 720. The transistors 740 may include additional features not depicted for the sake of clarity, such as device isolation regions, gate contacts, and the like. The transistors 740 are not limited to the type and configuration depicted in FIG. 7 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

FIGS. 8A-8D are simplified perspective views of example planar, FinFET, gate-all-around, and stacked gate-all-around transistors. The transistors illustrated in FIGS. 8A-8D are formed on a substrate 816 having a surface 808. Isolation regions 814 separate the source and drain regions of the transistors from other transistors and from a bulk region 818 of the substrate 816.

FIG. 8A is a perspective view of an example planar transistor 800 comprising a gate 802 that controls current flow between a source region 804 and a drain region 806. The transistor 800 is planar in that the source region 804 and the drain region 806 are planar with respect to the substrate surface 808.

FIG. 8B is a perspective view of an example FinFET transistor 820 comprising a gate 822 that controls current flow between a source region 824 and a drain region 826. The transistor 820 is non-planar in that the source region 824 and the drain region 826 comprise “fins” that extend upwards from the substrate surface 808. As the gate 822 encompasses three sides of the semiconductor fin that extends from the source region 824 to the drain region 826, the transistor 820 can be considered a tri-gate transistor. FIG. 8B illustrates one S/D fin extending through the gate 822, but multiple S/D fins can extend through the gate of a FinFET transistor.

FIG. 8C is a perspective view of a gate-all-around (GAA) transistor (GAAFET) 840 comprising a gate 842 that controls current flow between a source region 844 and a drain region 846 of a strip 848 comprising a semiconductor (semiconductor strip). The transistor 840 is non-planar in that the strip 848 is elevated from the substrate surface 808.

FIG. 8D is a perspective view of a GAA transistor 860 comprising a gate 862 that controls current flow between source regions 864 and drain regions 866 of multiple elevated semiconductor strips 868. The transistor 860 is a stacked GAA transistor as the gate controls the flow of current between multiple elevated S/D regions stacked on top of each other. The transistors 840 and 860 can be referred to as gate-all-around transistors as the gates encompass all sides of the portions of the semiconductor strips that extend from the source regions to the drain regions. The transistors 840 and 860 can alternatively be referred to as nanowire, nanosheet, or nanoribbon transistors and the semiconductor strips that pass through the gate region can be referred to as nanowires, nanowires, or nanoribbons.

FIGS. 9A and 9B are simplified perspective and cross-sectional views of example forksheet gate-all-around transistors. The forksheet transistors 960 are formed on a substrate 916 having a surface 908. The substrate 916 comprises an isolation region 914 located on top of a bulk region 918. The forksheet transistors 960 are similar to the stacked GAA transistor 860 of FIG. 8D, but with an isolation wall 970 located between stacked n-type and p-type source regions and stacked n-type and p-type drain regions. The forksheet transistors 960 comprise a gate 962 that controls flow between multiple n-type elevated source regions 964 and multiple n-type elevated drain regions 966, and multiple p-type elevated source regions 972 and multiple p-type elevated drain regions 974. FIG. 9B is a cross-sectional view of the forksheet transistors 960 taken along the line A-A′ of FIG. 9A. Channel regions 965 connect n-type source regions 964 to n-type drain regions 966, channel regions 973 connect p-type source regions 970 to p-type drain regions 972, and isolation region 980 separates the channel regions 965 from the channel regions 973 and connects isolation region 970 to isolation region 982. Thus, the forksheet transistors 960 comprise an n-type transistor comprising n-type source regions 964, channel region 965, n-type drain regions 966 and gate 962; and a p-type transistor comprising p-type source regions 972, channel regions 974, p-type drain regions 973, and gate 962. The gate 962 is shared by the forksheet transistors 960. Forksheet transistors 960 can provide for reduced spacing between n-type and p-type S/D regions in adjacent transistors relative to GAA transistors and can thus allow for increased transistor density relative to GAA transistors or increased active transistor width at the same transistor density as GAA transistors.

FIGS. 10A-10B are simplified perspective and cross-sectional views, respectively, of an example complementary field-effect-transistor (CFET) architecture. FIG. 10B is a cross-sectional view of the CFET architecture 1040 taken along the line B-B′ of FIG. 10A. The CFET architecture 1040 comprises vertically stacked gate-all-around transistors 1042 and 1044. In FIGS. 10A-10B, transistor 1042 is an n-type transistor and transistor 1044 is a p-type transistor, but in other embodiments, a CFET architecture can comprise an n-type transistor located above a p-type transistor. The transistors 1042 and 1044 are formed on a substrate 1016 having a surface 1008. The substrate 1016 comprises an isolation region 1014 located on top of a bulk region 1018.

The n-type and p-type transistors 1042 and 1044 comprise a gate 1082 shared by both transistors that controls current flow between multiple elevated source regions and multiple elevated drain regions 1074. The n-type transistor 1042 comprises n-type source regions 1072 connected to n-type drain regions 1074 by channel regions 1073 and the p-type transistor 1044 comprises p-type source regions 1064 connected to p-type drain regions 1066 by channel regions 1065. The transistor stacking employed by the CFET architecture can provide for improved transistor density in the x- and y-dimensions or increased transistor width at the same transistor density relative to other gate-all-around transistor architectures, such as those illustrated in FIGS. 9B, 10A, and 10B. In some embodiments, the CFET architecture 1040 can be formed monolithically, with the upper and lower transistors being formed on the same substrate, or sequentially, with the lower transistor (e.g., 1040) formed on a first substrate and the upper transistor (e.g., 1042) formed on a second substrate, with the upper transistor integrated with the lower transistor through transfer of the upper transistor from the second substrate to the first substrate.

Returning to FIG. 7, a transistor 740 may include a gate 722 formed of at least two layers, a gate dielectric, and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 740 along the source-channel-drain direction, the gate electrode may consist of a U-shaped structure that includes a bottom portion substantially parallel to the surface of the die substrate 702 and two sidewall portions that are substantially perpendicular to the top surface of the die substrate 702. In other embodiments, at least one of the metal layers that form the gate electrode may simply be a planar layer that is substantially parallel to the top surface of the die substrate 702 and does not include sidewall portions substantially perpendicular to the top surface of the die substrate 702. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 720 may be formed within the die substrate 702 adjacent to the gate 722 of individual transistors 740. The S/D regions 720 may be formed using an implantation/diffusion process or an etching/deposition process, for example. In the former process, dopants such as boron, aluminum, antimony, phosphorous, or arsenic may be ion-implanted into the die substrate 702 to form the S/D regions 720. An annealing process that activates the dopants and causes them to diffuse farther into the die substrate 702 may follow the ion-implantation process. In the latter process, the die substrate 702 may first be etched to form recesses at the locations of the S/D regions 720. An epitaxial deposition process may then be carried out to fill the recesses with material that is used to fabricate the S/D regions 720. In some implementations, the S/D regions 720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 720 may be formed using one or more alternate semiconductor materials such as germanium or a group III-V material or alloy. In further embodiments, one or more layers of metal and/or metal alloys may be used to form the S/D regions 720.

Electrical signals, such as power and/or input/output (I/O) signals, may be routed to and/or from the devices (e.g., transistors 740) of the device layer 704 through one or more interconnect layers disposed on the device layer 704 (illustrated in FIG. 7 as interconnect layers 706-710). For example, electrically conductive features of the device layer 704 (e.g., the gate 722 and the S/D contacts 724) may be electrically coupled with the interconnect structures 728 of the interconnect layers 706-710. The one or more interconnect layers 706-710 may form a metallization stack (also referred to as an “ILD stack”) 719 of the integrated circuit device 700.

The interconnect structures 728 may be arranged within the interconnect layers 706-710 to route electrical signals according to a wide variety of designs; in particular, the arrangement is not limited to the particular configuration of interconnect structures 728 depicted in FIG. 7. Although a particular number of interconnect layers 706-710 is depicted in FIG. 7, embodiments of the present disclosure include integrated circuit devices having more or fewer interconnect layers than depicted.

In some embodiments, the interconnect structures 728 may include lines 728a and/or vias 728b filled with an electrically conductive material such as a metal. The lines 728a may be arranged to route electrical signals in a direction of a plane that is substantially parallel with a surface of the die substrate 702 upon which the device layer 704 is formed. For example, the lines 728a may route electrical signals in a direction in and out of the page and/or in a direction across the page from the perspective of FIG. 7 The vias 728b may be arranged to route electrical signals in a direction of a plane that is substantially perpendicular to the surface of the die substrate 702 upon which the device layer 704 is formed. In some embodiments, the vias 728b may electrically couple lines 728a of different interconnect layers 706-710 together.

The interconnect layers 706-710 may include a dielectric material 726 disposed between the interconnect structures 728, as shown in FIG. 7. In some embodiments, dielectric material 726 disposed between the interconnect structures 728 in different ones of the interconnect layers 706-710 may have different compositions; in other embodiments, the composition of the dielectric material 726 between different interconnect layers 706-710 may be the same. The device layer 704 may include a dielectric material 726 disposed between the transistors 740 and a bottom layer of the metallization stack as well. The dielectric material 726 included in the device layer 704 may have a different composition than the dielectric material 726 included in the interconnect layers 706-710; in other embodiments, the composition of the dielectric material 726 in the device layer 704 may be the same as a dielectric material 726 included in any one of the interconnect layers 706-710.

A first interconnect layer 706 (referred to as Metal 1 or “M1”) may be formed directly on the device layer 704. In some embodiments, the first interconnect layer 706 may include lines 728a and/or vias 728b, as shown. The lines 728a of the first interconnect layer 706 may be coupled with contacts (e.g., the S/D contacts 724) of the device layer 704. The vias 728b of the first interconnect layer 706 may be coupled with the lines 728a of a second interconnect layer 708.

The second interconnect layer 708 (referred to as Metal 2 or “M2”) may be formed directly on the first interconnect layer 706. In some embodiments, the second interconnect layer 708 may include via 728b to couple the lines 728 of the second interconnect layer 708 with the lines 728a of a third interconnect layer 710. Although the lines 728a and the vias 728b are structurally delineated with a line within individual interconnect layers for the sake of clarity, the lines 728a and the vias 728b may be structurally and/or materially contiguous (e.g., simultaneously filled during a dual-damascene process) in some embodiments.

The third interconnect layer 710 (referred to as Metal 3 or “M3”) (and additional interconnect layers, as desired) may be formed in succession on the second interconnect layer 708 according to similar techniques and configurations described in connection with the second interconnect layer 708 or the first interconnect layer 706. In some embodiments, the interconnect layers that are “higher up” in the metallization stack 719 in the integrated circuit device 700 (i.e., farther away from the device layer 704) may be thicker than the interconnect layers that are lower in the metallization stack 719, with lines 728a and vias 728b in the higher interconnect layers being thicker than those in the lower interconnect layers.

The integrated circuit device 700 may include a solder resist material 734 (e.g., polyimide or similar material) and one or more conductive contacts 736 formed on the interconnect layers 706-710. In FIG. 7, the conductive contacts 736 are illustrated as taking the form of bond pads. The conductive contacts 736 may be electrically coupled with the interconnect structures 728 and configured to route the electrical signals of the transistor(s) 740 to external devices. For example, solder bonds may be formed on the one or more conductive contacts 736 to mechanically and/or electrically couple an integrated circuit die including the integrated circuit device 700 with another component (e.g., a printed circuit board). The integrated circuit device 700 may include additional or alternate structures to route the electrical signals from the interconnect layers 706-710; for example, the conductive contacts 736 may include other analogous features (e.g., posts) that route the electrical signals to external components.

In some embodiments in which the integrated circuit device 700 is a double-sided die, the integrated circuit device 700 may include another metallization stack (not shown) on the opposite side of the device layer(s) 704. This metallization stack may include multiple interconnect layers as discussed above with reference to the interconnect layers 706-710, to provide conductive pathways (e.g., including conductive lines and vias) between the device layer(s) 704 and additional conductive contacts (not shown) on the opposite side of the integrated circuit device 700 from the conductive contacts 736.

In other embodiments in which the integrated circuit device 700 is a double-sided die, the integrated circuit device 700 may include one or more through silicon vias (TSVs) through the die substrate 702; these TSVs may make contact with the device layer(s) 704, and may provide conductive pathways between the device layer(s) 704 and additional conductive contacts (not shown) on the opposite side of the integrated circuit device 700 from the conductive contacts 736. In some embodiments, TSVs extending through the substrate can be used for routing power and ground signals from conductive contacts on the opposite side of the integrated circuit device 700 from the conductive contacts 736 to the transistors 740 and any other components integrated into the die 700, and the metallization stack 719 can be used to route I/O signals from the conductive contacts 736 to transistors 740 and any other components integrated into the die 700.

Multiple integrated circuit devices 700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

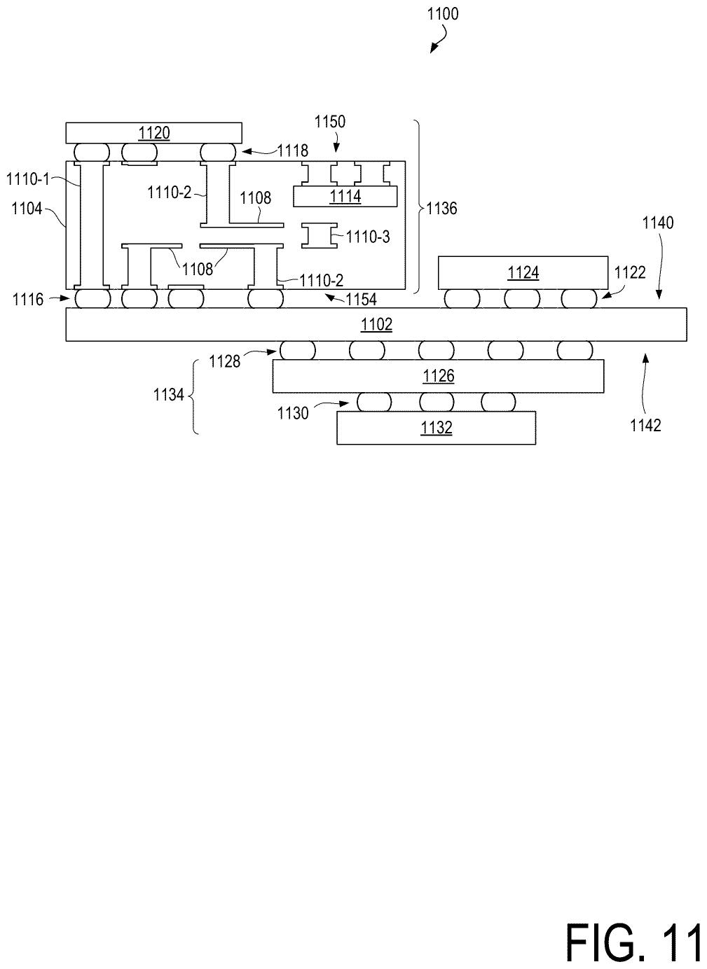

FIG. 11 is a cross-sectional side view of an integrated circuit device assembly 1100 that may include any of the microelectronic assemblies disclosed herein. The integrated circuit device assembly 1100 includes a number of components disposed on a circuit board 1102 (which may be a motherboard, system board, mainboard, etc.). The integrated circuit device assembly 1100 includes components disposed on a first face 1140 of the circuit board 1102 and an opposing second face 1142 of the circuit board 1102; generally, components may be disposed on one or both faces 1140 and 1142. Any of the integrated circuit components discussed below with reference to the integrated circuit device assembly 1100 may take the form of any suitable ones of the embodiments of the microelectronic assemblies disclosed herein.

In some embodiments, the circuit board 1102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1102. In other embodiments, the circuit board 1102 may be a non-PCB substrate. The integrated circuit device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1116 may serve as the coupling components illustrated or described for any of the substrate assembly or substrate assembly components described herein, as appropriate.

The package-on-interposer structure 1136 may include an integrated circuit component 1120 coupled to an interposer 1104 by coupling components 1118. The coupling components 1118 may take any suitable form for the application, such as the forms discussed above with reference to the coupling components 1116. Although a single integrated circuit component 1120 is shown in FIG. 11, multiple integrated circuit components may be coupled to the interposer 1104; indeed, additional interposers may be coupled to the interposer 1104. The interposer 1104 may provide an intervening substrate used to bridge the circuit board 1102 and the integrated circuit component 1120.

The integrated circuit component 1120 may be a packaged or unpackaged integrated circuit product that includes one or more integrated circuit dies (e.g., the die 602 of FIG. 6, the integrated circuit device 700 of FIG. 7) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1120, a single monolithic integrated circuit die comprises solder bumps attached to contacts on the die. The solder bumps allow the die to be directly attached to the interposer 1104. The integrated circuit component 1120 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1120 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1120 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1120 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1104 may spread connections to a wider pitch or reroute a connection to a different connection. For example, the interposer 1104 may couple the integrated circuit component 1120 to a set of ball grid array (BGA) conductive contacts of the coupling components 1116 for coupling to the circuit board 1102. In the embodiment illustrated in FIG. 11, the integrated circuit component 1120 and the circuit board 1102 are attached to opposing sides of the interposer 1104; in other embodiments, the integrated circuit component 1120 and the circuit board 1102 may be attached to a same side of the interposer 1104. In some embodiments, three or more components may be interconnected by way of the interposer 1104.

In some embodiments, the interposer 1104 may be formed as a PCB, including multiple metal layers separated from one another by layers of dielectric material and interconnected by electrically conductive vias. In some embodiments, the interposer 1104 may be formed of an epoxy resin, a fiberglass-reinforced epoxy resin, an epoxy resin with inorganic fillers, a ceramic material, or a polymer material such as polyimide. In some embodiments, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through hole vias 1110-1 (that extend from a first face 1150 of the interposer 1104 to a second face 1154 of the interposer 1104), blind vias 1110-2 (that extend from the first or second faces 1150 or 1154 of the interposer 1104 to an internal metal layer), and buried vias 1110-3 (that connect internal metal layers).

In some embodiments, the interposer 1104 can comprise a silicon interposer. Through silicon vias (TSV) extending through the silicon interposer can connect connections on a first face of a silicon interposer to an opposing second face of the silicon interposer. In some embodiments, an interposer 1104 comprising a silicon interposer can further comprise one or more routing layers to route connections on a first face of the interposer 1104 to an opposing second face of the interposer 1104.

The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The integrated circuit device assembly 1100 may include an integrated circuit component 1124 coupled to the first face 1140 of the circuit board 1102 by coupling components 1122. The coupling components 1122 may take the form of any of the embodiments discussed above with reference to the coupling components 1116, and the integrated circuit component 1124 may take the form of any of the embodiments discussed above with reference to the integrated circuit component 1120.

The integrated circuit device assembly 1100 illustrated in FIG. 11 includes a package-on-package structure 1134 coupled to the second face 1142 of the circuit board 1102 by coupling components 1128. The package-on-package structure 1134 may include an integrated circuit component 1126 and an integrated circuit component 1132 coupled together by coupling components 1130 such that the integrated circuit component 1126 is disposed between the circuit board 1102 and the integrated circuit component 1132. The coupling components 1128 and 1130 may take the form of any of the embodiments of the coupling components 1116 discussed above, and the integrated circuit components 1126 and 1132 may take the form of any of the embodiments of the integrated circuit component 1120 discussed above. The package-on-package structure 1134 may be configured in accordance with any of the package-on-package structures known in the art.

FIG. 12 is a block diagram of an example electrical device 1200 that may include integrated circuit die comprising TMD monolayers transferred from a growth layer and/or one or more of the microelectronic assemblies disclosed herein. For example, any suitable ones of the components of the electrical device 1200 may include one or more of the integrated circuit device assemblies 1100, integrated circuit components 1120, integrated circuit devices 700, or integrated circuit dies 602, 400 disclosed herein, and may be arranged in any of the microelectronic assemblies disclosed herein. A number of components are illustrated in FIG. 12 as included in the electrical device 1200, but any one or more of these components may be omitted or duplicated, as suitable for the application. In some embodiments, some or all of the components included in the electrical device 1200 may be attached to one or more motherboards mainboards, or system boards. In some embodiments, one or more of these components are fabricated onto a single system-on-a-chip (SoC) die.

Additionally, in various embodiments, the electrical device 1200 may not include one or more of the components illustrated in FIG. 12, but the electrical device 1200 may include interface circuitry for coupling to the one or more components. For example, the electrical device 1200 may not include a display device 1206, but may include display device interface circuitry (e.g., a connector and driver circuitry) to which a display device 1206 may be coupled. In another set of examples, the electrical device 1200 may not include an audio input device 1224 or an audio output device 1208, but may include audio input or output device interface circuitry (e.g., connectors and supporting circuitry) to which an audio input device 1224 or audio output device 1208 may be coupled.

The electrical device 1200 may include one or more processor units 1202 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1202 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1200 may include a memory 1204, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1204 may include memory that is located on the same integrated circuit die as the processor unit 1202. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1200 can comprise one or more processor units 1202 that are heterogeneous or asymmetric to another processor unit 1202 in the electrical device 1200. There can be a variety of differences between the processing units 1202 in a system in terms of a spectrum of metrics of merit including architectural, microarchitectural, thermal, power consumption characteristics, and the like. These differences can effectively manifest themselves as asymmetry and heterogeneity among the processor units 1202 in the electrical device 1200.

In some embodiments, the electrical device 1200 may include a communication component 1212 (e.g., one or more communication components). For example, the communication component 1212 can manage wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1212 may operate in accordance with other wireless protocols in other embodiments. The electrical device 1200 may include an antenna 1222 to facilitate wireless communications and/or to receive other wireless communications (such as AM or FM radio transmissions).

In some embodiments, the communication component 1212 may manage wired communications, such as electrical, optical, or any other suitable communication protocols (e.g., IEEE 802.3 Ethernet standards). As noted above, the communication component 1212 may include multiple communication components. For instance, a first communication component 1212 may be dedicated to shorter-range wireless communications such as Wi-Fi or Bluetooth, and a second communication component 1212 may be dedicated to longer-range wireless communications such as global positioning system (GPS), EDGE, GPRS, CDMA, WiMAX, LTE, EV-DO, or others. In some embodiments, a first communication component 1212 may be dedicated to wireless communications, and a second communication component 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display device 1206 (or corresponding interface circuitry, as discussed above). The display device 1206 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any embedded or wired or wirelessly connected external device that generates an audible indicator, such as speakers, headsets, or earbuds.

The electrical device 1200 may include an audio input device 1224 (or corresponding interface circuitry, as discussed above). The audio input device 1224 may include any embedded or wired or wirelessly connected device that generates a signal representative of a sound, such as microphones, microphone arrays, or digital instruments (e.g., instruments having a musical instrument digital interface (MIDI) output). The electrical device 1200 may include a Global Navigation Satellite System (GNSS) device 1218 (or corresponding interface circuitry, as discussed above), such as a Global Positioning System (GPS) device. The GNSS device 1218 may be in communication with a satellite-based system and may determine a geolocation of the electrical device 1200 based on information received from one or more GNSS satellites, as known in the art.

The electrical device 1200 may include an other output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include an other input device 1220 (or corresponding interface circuitry, as discussed above). Examples of the other input device 1220 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1200 may be any other electronic device that processes data. In some embodiments, the electrical device 1200 may comprise multiple discrete physical components. Given the range of devices that the electrical device 1200 can be manifested as in various embodiments, in some embodiments, the electrical device 1200 can be referred to as a computing device or a computing system.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C. Furthermore, as used in this application and the claims, a list of items joined by the term “one of” can mean any one of the listed items. For example, the phrase “one of A, B, and C” can mean A, B, or C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus comprising: a substrate; a monolayer positioned above the substrate, the monolayer comprising a transition metal dichalcogenide or transition metal dichalcogenide alloy; a first layer positioned adjacent to a surface of the monolayer; and a plurality of metal atoms at an interface between the monolayer and the first layer.

Example 2 comprises the apparatus of Example 1, wherein the plurality of metal atoms is a first plurality of metal atoms, the apparatus further comprising a second plurality of metal atoms in the first layer.

Example 3 comprises the apparatus of Example 1 or 2, wherein the first layer comprises oxygen.

Example 4 comprises the apparatus of any one of Examples 1-3, further comprising a second layer positioned between the monolayer and the substrate, wherein the second layer comprises an atomic composition of about 0.1% or less of sulfur, selenium, or tellurium at an interface between the monolayer and the second layer.

Example 5 comprises the apparatus of any one of Examples 1-3, further comprising a second layer positioned between the monolayer and the substrate, wherein there is no sulfur, selenium, or tellurium in the second layer.

Example 6 comprises the apparatus of Example 4 or 5, wherein the second layer comprises oxygen.

Example 7 comprises the apparatus of Example 4 or 5, wherein a thickness of the second layer is about 500 nanometers or less.

Example 8 comprises the apparatus of Example 1, wherein the monolayer is positioned adjacent to the substrate and the substrate comprises an atomic composition of about 0.1% or less of sulfur, selenium, or tellurium at an interface between the monolayer and the substrate.

Example 9 comprises the apparatus of any one of Examples 1-8, wherein the plurality of metal atoms comprises antimony atoms.

Example 10 comprises the apparatus of any one of Examples 1-8, wherein the plurality of metal atoms comprises zinc atoms.

Example 11 comprises the apparatus of any one of Examples 1-8, wherein the plurality of metal atoms comprises tin atoms.

Example 12 comprises the apparatus of any one of Examples 1-8, wherein the plurality of metal atoms comprises platinum atoms.

Example 13 comprises the apparatus of any one of Examples 1-8, wherein the plurality of metal atoms comprises lead atoms.

Example 14 comprises the apparatus of any one of Examples 1-8, wherein the plurality of metal atoms comprises cobalt atoms.

Example 15 comprises the apparatus of any one of Examples 1-8, wherein the plurality of metal atoms comprises chromium atoms.

Example 16 comprises the apparatus of any one of Examples 1-8, wherein the plurality of metal atoms comprises ruthenium atoms.

Example 17 comprises the apparatus of any one of Examples 1-8, wherein the plurality of metal atoms comprises palladium atoms.

Example 18 comprises the apparatus of any one of Examples 1-8, wherein the plurality of metal atoms comprises manganese atoms.

Example 19 comprises the apparatus of any one of Examples 1-8, wherein the plurality of metal atoms comprises molybdenum atoms, the apparatus further comprising a plurality of oxygen atoms at the interface between the monolayer and the first layer.

Example 20 comprises the apparatus of any one of Examples 1-8, wherein the plurality of metal atoms comprises titanium atoms, the apparatus further comprising a plurality of nitrogen atoms at the interface between the monolayer and the first layer.

Example 21 comprises the apparatus of any one of Examples 1-8, wherein the plurality of metal atoms comprises silicon atoms, the apparatus further comprising a plurality of oxygen atoms at the interface between the monolayer and the first layer.

Example 22 comprises the apparatus of any one of Examples 1-8, wherein the plurality of metal atoms comprises hafnium atoms, the apparatus further comprising a plurality of oxygen atoms at the interface between the monolayer and the first layer.

Example 23 comprises the apparatus of any one of Examples 1-8, wherein the plurality of metal atoms comprises titanium atoms, the apparatus further comprising a plurality of oxygen atoms at the interface between the monolayer and the first layer.

Example 24 comprises the apparatus of any one of Examples 1-8, wherein the plurality of metal atoms comprises aluminum atoms, the apparatus further comprising a plurality of oxygen atoms at the interface between the monolayer and the first layer.

Example 25 comprises the apparatus of any one of Examples 1-8, wherein the plurality of metal atoms comprises silicon atoms, the apparatus further comprising a plurality of nitrogen atoms at the interface between the monolayer and the first layer.

Example 26 comprises the apparatus of any one of Examples 1-25, wherein the substrate comprises silicon.

Example 27 comprises the apparatus of any one of Examples 1-26, wherein the transition metal dichalcogenide comprises: a transition metal; and sulfur, selenium, or tellurium.

Example 28 comprises the apparatus of Example 27, wherein the transition metal is titanium.

Example 29 comprises the apparatus of Example 27, wherein the transition metal is molybdenum.

Example 30 comprises the apparatus of Example 27, wherein the transition metal is tungsten.

Example 31 comprises the apparatus of Example 27, wherein the transition metal is platinum.

Example 32 comprises the apparatus of Example 27, wherein the transition metal is erbium.

Example 33 comprises the apparatus of Example 27, wherein the transition metal is lanthanum.

Example 34 comprises the apparatus of Example 27, wherein the transition metal is rhodium.

Example 35 comprises the apparatus of Example 27, wherein the transition metal is niobium.

Example 36 comprises the apparatus of any one of Examples 1-26, wherein the transition metal dichalcogenide alloy comprises: a first transition metal and a second transition metal; and sulfur, selenium, or tellurium.

Example 37 comprises the apparatus of Example 36, wherein the first transition metal is titanium, molybdenum, tungsten, platinum, erbium, lanthanum, rhodium, or niobium; and the second transition metal is titanium, molybdenum, tungsten, platinum, erbium, lanthanum, rhodium, or niobium, the first transition metal different than the second transition metal.

Example 38 comprises the apparatus of any one of Examples 1-3 or 6-37, wherein the monolayer is a first monolayer, the apparatus further comprising: a second monolayer positioned above and adjacent to the first layer, the second monolayer comprising the transition metal dichalcogenide or the transition metal dichalcogenide alloy; and a second layer positioned adjacent to and above the second monolayer.

Example 39 comprises the apparatus of Example 38, wherein the plurality of metal atoms is a first plurality of metal atoms, the apparatus further comprising a second plurality of metal atoms at an interface between the second layer and the second monolayer, the second plurality of metal atoms comprising antimony, zinc, tin, platinum, lead, cobalt, chromium, ruthenium, palladium, or manganese.

Example 40 comprises the apparatus of Example 38 or 39, wherein the first layer comprises an atomic composition of about 0.1% or less of sulfur, selenium, or tellurium.

Example 41 comprises the apparatus of Example 38 or 39, wherein there is no sulfur, selenium, or tellurium in the first layer.

Example 42 comprises the apparatus of any one of Examples 1-41, further comprising a field effect transistor, wherein the first layer, the monolayer, and the field effect transistor are located in an integrated circuit die having a die edge, the first layer and the monolayer positioned laterally between the field effect transistor and the die edge.

Example 43 comprises the apparatus of any of Examples 1-37 or 42 wherein the apparatus is an integrated circuit component comprising the monolayer, the first layer, and the substrate.

Example 44 comprises the apparatus of Example 43, wherein the integrated circuit component is attached to a printed circuit board.

Example 45 comprises the apparatus of Example 44, wherein the integrated circuit component is a first integrated circuit component and one or more second integrated circuit components are attached to the printed circuit board.

Example 46 is an apparatus comprising: a substrate; a first monolayer positioned above the substrate; a second monolayer positioned above the first monolayer; a first layer positioned between and adjacent to the first monolayer and the second monolayer; a third monolayer positioned above the substrate, the third monolayer substantially coplanar with the first monolayer; a fourth monolayer positioned above the third monolayer the fourth monolayer substantially coplanar with the second monolayer, wherein the first monolayer, the second monolayer, the third monolayer, and the fourth monolayer comprise a transition metal dichalcogenide or a transition metal dichalcogenide alloy; a second layer positioned between the third monolayer and the fourth monolayer, the second layer positioned adjacent to the third monolayer, a third layer positioned between the third monolayer and the fourth monolayer, the third layer positioned adjacent to the fourth monolayer; and a fourth layer positioned between the second layer and the third layer, the fourth layer comprising a metal.

Example 47 comprises the apparatus of Example 46, further comprising a plurality of metal atoms at an interface between the first monolayer and the first layer, the plurality of metal atoms comprising antimony, zinc, tin, platinum, lead, cobalt, chromium, ruthenium, palladium, or manganese.

Example 48 comprises the apparatus of Example 46 or 47, wherein the first layer comprises an atomic composition of about 0.1% or less of sulfur, selenium or tellurium at an interface between the second monolayer and the first layer.

Example 49 comprises the apparatus of Example 46 or 47, wherein there is no sulfur, selenium, or tellurium in the first layer.

Example 50 comprises the apparatus of any one of Examples 46-49, wherein the third monolayer and the fourth monolayer are channel regions of a field effect transistor.

Example 51 comprises the apparatus of Example 50, wherein the fourth layer is at least part of a gate electrode region for the field effect transistor.

Example 52 comprises the apparatus of any one of Examples 46-51, wherein the transition metal dichalcogenide comprises: a transition metal; and sulfur, selenium, or tellurium.

Example 53 comprises the apparatus of Example 52, wherein the transition metal is titanium, molybdenum, tungsten, platinum, erbium, lanthanum, rhodium, or niobium.

Example 54 comprises the apparatus of any one of Examples 46-53, wherein the transition metal dichalcogenide alloy comprises: a first transition metal and a second transition metal; and sulfur, selenium, or tellurium.

Example 55 comprises the apparatus of Example 54, wherein the first transition metal is titanium, molybdenum, tungsten, platinum, erbium, lanthanum, rhodium, or niobium; and the second transition metal is titanium, molybdenum, tungsten, platinum, erbium, lanthanum, rhodium, or niobium, the first transition metal different than the second transition metal.

Example 56 is a method comprising: forming a monolayer on a first substrate, the monolayer comprising a transition metal dichalcogenide or a transition metal dichalcogenide alloy; forming a first layer on a surface of the monolayer; attaching a carrier wafer to the first layer, wherein a carrier wafer stack comprises the monolayer, the first layer, and the carrier wafer; separating the carrier wafer stack from the first substrate; attaching the carrier wafer stack to a second substrate; and separating the first layer and the carrier wafer from the monolayer.

Example 57 comprises the method of Example 56, further comprising forming a second layer on the surface of the monolayer after separating the first layer and the carrier wafer from the monolayer.

Example 58 comprises the method of Example 57, wherein the second layer comprises oxygen.

Example 59 comprises the method of Example 57, wherein a plurality of metal atoms is located at an interface between the monolayer and the second layer, the plurality of metal atoms comprising antimony, zinc, tin, platinum, lead, cobalt, chromium, ruthenium, palladium, or manganese.

Example 60 comprises the method of Example 56, wherein the monolayer is positioned adjacent to the second substrate and the first substrate comprises an atomic composition of 0.1% or less of sulfur, selenium, or tellurium at an interface between the monolayer and the second substrate.

Example 61 comprises the method of Example 56, wherein there is no sulfur, selenium, or tellurium in the second substrate.

Example 62 comprises the method of any one of Examples 56-61, the second substrate comprising a third layer located on a surface of the second substrate, attaching the carrier wafer stack to the second substrate comprising attaching the carrier wafer stack to the third layer, the third layer positioned between the second substrate and the monolayer after attachment of the carrier wafer stack to the third layer, the third layer comprising oxygen.

Example 63 comprises the method of Example 62, wherein the third layer comprises an atomic composition of 0.1% or less of sulfur, selenium, or tellurium at an interface between the monolayer and the third layer.

Example 64 comprises the method of Example 62, wherein the third layer does not comprise sulfur, selenium or tellurium.

Example 65 comprises the method of any one of Examples 56-61, wherein the transition metal dichalcogenide comprises: a transition metal; and sulfur, selenium, or tellurium.

Example 66 comprises the method of Example 65, wherein the transition metal is titanium, molybdenum, tungsten, platinum, erbium, lanthanum, rhodium, or niobium.

Example 67 comprises the method of any one of Examples 56-61, wherein the transition metal dichalcogenide alloy comprises: a first transition metal and a second transition metal; and sulfur, selenium, or tellurium.

Example 68 comprises the method of Example 67, wherein the first transition metal is titanium, molybdenum, tungsten, platinum, erbium, lanthanum, rhodium, or niobium; and the second transition metal is titanium, molybdenum, tungsten, platinum, erbium, lanthanum, rhodium, or niobium, the first transition metal different than the second transition metal.

Example 69 comprises the method of Example 46, further comprising a plurality of molecules between the first monolayer and the first layer, the plurality of molecules comprising: molybdenum and oxygen; titanium and nitrogen; silicon and oxygen; hafnium and oxygen; titanium and oxygen; aluminum and oxygen; or silicon and nitrogen.

Example 70 comprises the method of Example 57, wherein a plurality of molecules is located at an interface between the monolayer and the second layer, the plurality of molecules comprising: molybdenum and oxygen; titanium and nitrogen; silicon and oxygen; hafnium and oxygen; titanium and oxygen; aluminum and oxygen; or silicon and nitrogen.

1. An apparatus comprising:
a substrate;
a monolayer positioned above the substrate, the monolayer comprising a transition metal dichalcogenide or transition metal dichalcogenide alloy;
a first layer positioned adjacent to a surface of the monolayer; and
a plurality of metal atoms at an interface between the monolayer and the first layer.

2. The apparatus of claim 1, wherein the first layer comprises oxygen.

3. The apparatus of claim 1, further comprising a second layer positioned between the monolayer and the substrate, wherein the second layer comprises an atomic composition of about 0.1% or less of sulfur, selenium or tellurium at an interface between the monolayer and the second layer.

4. The apparatus of claim 1, wherein the monolayer is positioned adjacent to the substrate and the substrate comprises an atomic composition of about 0.1% or less of sulfur, selenium, or tellurium at an interface between the monolayer and the substrate.

5. The apparatus of claim 1, wherein the plurality of metal atoms comprises antimony atoms.

6. The apparatus of claim 1, wherein the plurality of metal atoms comprises zinc, tin, platinum, lead, cobalt, chromium, ruthenium, palladium, or manganese atoms.

7. The apparatus of claim 1, wherein the transition metal dichalcogenide comprises:
titanium, molybdenum, tungsten, platinum, erbium, lanthanum, niobium, or rhodium; and
sulfur, selenium, or tellurium.

8. The apparatus of claim 1, further comprising a field effect transistor, wherein the first layer, the monolayer, and the field effect transistor are located in an integrated circuit die having a die edge, the first layer and the monolayer positioned laterally between the field effect transistor and the die edge.

9. The apparatus of claim 1 wherein the apparatus further comprises an integrated circuit component comprising the monolayer, the first layer, and the substrate.

10. The apparatus of claim 9 wherein the apparatus further comprises a printed circuit board, the integrated circuit component attached to the printed circuit board.

11. An apparatus comprising:
a substrate;
a first monolayer positioned above the substrate;
a second monolayer positioned above the first monolayer;
a first layer positioned between and adjacent to the first monolayer and the second monolayer;
a third monolayer positioned above the substrate, the third monolayer substantially coplanar with the first monolayer;
a fourth monolayer positioned above the third monolayer the fourth monolayer substantially coplanar with the second monolayer, wherein the first monolayer, the second monolayer, the third monolayer, and the fourth monolayer comprise a transition metal dichalcogenide or a transition metal dichalcogenide alloy;
a second layer positioned between the third monolayer and the fourth monolayer, the second layer positioned adjacent to the third monolayer,
a third layer positioned between the third monolayer and the fourth monolayer, the third layer positioned adjacent to the fourth monolayer; and
a fourth layer positioned between the second layer and the third layer, the fourth layer comprising a metal.

12. The apparatus of claim 11, further comprising a plurality of metal atoms at an interface between the first monolayer and the first layer, the plurality of metal atoms comprising antimony, zinc, tin, platinum, lead, cobalt, chromium, ruthenium, palladium, or manganese atoms.

13. The apparatus of claim 11, wherein the first layer comprises an atomic composition of about 0.1% or less of sulfur, selenium, or tellurium at an interface between the second monolayer and the first layer.

14. The apparatus of claim 11, wherein the third monolayer and the fourth monolayer are channel regions of a field effect transistor, and the fourth layer is at least part of a gate electrode region for the field effect transistor.

15. The apparatus of claim 11, wherein the transition metal dichalcogenide comprises:
titanium, molybdenum, tungsten, platinum, erbium, lanthanum, niobium, or rhodium; and
sulfur, selenium, or tellurium.

16. A method comprising:
forming a monolayer on a first substrate, the monolayer comprising a transition metal dichalcogenide or a transition metal dichalcogenide alloy;
forming a first layer on a surface of the monolayer;
attaching a carrier wafer to the first layer, wherein a carrier wafer stack comprises the monolayer, the first layer, and the carrier wafer;
separating the carrier wafer stack from the first substrate;
attaching the carrier wafer stack to a second substrate; and
separating the first layer and the carrier wafer from the monolayer.

17. The method of claim 16, further comprising forming a second layer on the surface of the monolayer after separating the first layer and the carrier wafer from the monolayer.

18. The method of claim 17, wherein a plurality of metal atoms is located at an interface between the monolayer and the second layer, the plurality of metal atoms comprising antimony, zinc, tin, platinum, lead, cobalt, chromium, ruthenium, palladium, or manganese atoms.

19. The method of claim 16, wherein the monolayer is positioned adjacent to the second substrate and the first substrate comprises an atomic composition of 0.1% or less of sulfur, selenium, or tellurium at an interface between the monolayer and the second substrate.

20. The method of claim 16, wherein the transition metal dichalcogenide comprises:
titanium, molybdenum, tungsten, platinum, erbium, lanthanum, niobium, or rhodium; and
sulfur, selenium, or tellurium.
